(19) United States
(12) Patent Application Publication
(10) Pub. No.: US 2011/0097516 A1
(43) Pub. Date: Apr. 28, 2011

(54) PLASMA PROCESSING APPARATUS AND PLASMA PROCESSING METHOD

(75) Inventors: Hiroyuki MAKINO, Kanagawa (JP); Masaru TANAKA, Kanagawa (JP)

(73) Assignee: SUMITOMO HEAVY INDUSTRIES, LTD., Tokyo (JP)

(21) Appl. No.: 12/984,991

(22) Filed: Jan. 5, 2011

Related U.S. Application Data
(63) Continuation of application No. PCT/JP2009/062575, filed on Jul. 10, 2009.

(30) Foreign Application Priority Data
Jul. 11, 2008 (JP) 2008-180923

(51) Int. Cl. C23C 16/50; C23C 16/458

(52) U.S. Cl. 427/569; 118/723 R

(57) ABSTRACT

Provided is a plasma processing apparatus including: a plasma generator configured to generate plasma, and a conveyor configured to adjust a distance between a substrate and the plasma generator.

### RELATED APPLICATION

Priority is claimed to Japanese Patent Application No.2008-180923, filed Jul. 11, 2008, and International Patent Application No. PCT/JP2009/062575, the entire content of each of which is incorporated herein by reference.

### BACKGROUND

1. Technical Field

The present invention relates to a plasma processing apparatus and a plasma processing method conducted by the plasma processing apparatus.

2. Description of the Related Art

A plasma processing apparatus is an apparatus that performs thin film depositing, ion implanting, or the like on a substrate by using plasma, and is mainly used to fabricate semiconductors.

There are various types of structure for plasma processing apparatuses, but in general, an induced current is generated using a coil, and a gas is ionized.

Specifically, the plasma processing apparatus includes a chamber, a coil, and a chuck holding a substrate. The plasma processing apparatus evacuates the chamber, introduces a gas thereinto, and generates an induced current using the coil so as to make the gas be in a plasma state.

Then, the plasma processing apparatus applies a bias potential to the chuck by using a bias power source, and performs a plasma process on the surface of the substrate by using the generated plasma.

For example, a plasma processing apparatus is disclosed in paragraph “0004” of the pamphlet of WO2005/124844, in which a pair of parallel plate electrodes is disposed inside a chamber, a process gas is introduced into the chamber, and a high-frequency electric field is formed between the electrodes so as to form plasma.

### SUMMARY

According to an embodiment of the present invention, there is provided a plasma processing apparatus including: a plasma generator configured to generate plasma and a conveyor configured to adjust a distance between a substrate and the plasma generator.

According to another embodiment of the present invention, there is provided a plasma processing including: generating plasma by a plasma generator to perform a plasma process on a substrate and adjusting a distance between the substrate and the plasma generator.

### BRIEF DESCRIPTION OF THE DRAWINGS

FIG. 1 is a diagram illustrating a plasma processing apparatus.

FIG. 2 is a diagram illustrating the plasma processing apparatus when plasma is generated.

FIG. 3 is a diagram illustrating the plasma processing apparatus when plasma is generated.

FIG. 4 is a diagram illustrating the plasma processing apparatus when plasma is generated.

FIG. 5 is a diagram illustrating the plasma processing apparatus when plasma is generated.

FIG. 6 is a diagram illustrating the plasma processing apparatus when plasma is generated.

FIG. 7 is a diagram illustrating the relationship between non-uniformity of an in-plane resistance value of a substrate and the distance from the plasma processing apparatus to the substrate.

### DETAILED DESCRIPTION

In the plasma processing apparatus, since the distribution of ions deposited on or implanted into the substrate is dependent on the distribution of the plasma, the distribution of the plasma on the substrate needs to be uniform in order to make the distribution of the ions or deposited substances on the substrate uniform.

However, the distribution of the plasma is not uniform inside the chamber, and the density is different. For this reason, in order to make the distribution of the plasma on the substrate uniform by using the plasma processing apparatus, the gas pressure, output of the plasma power source, gas flow rate, and the like need to be adjusted.

Since such adjustment changes characteristics such as electron density, the temperature, or the like of the plasma itself, a problem arises in that adjustment is very difficult.

It is desirable to provide a plasma processing apparatus capable of making the distribution of the plasma on the substrate uniform without changing the characteristics of the plasma itself.

The plasma processing apparatus may further include: a holder which holds the substrate; and a biasing power source which applies a bias potential to the holder.

The conveyor may be a unit which adjusts the distance between the substrate and the plasma generator so that the sheath surface of a sheath generated on the surface of the holder during the plasma process is located at a position where the density distribution of the plasma becomes uniform.

The conveyor may be a unit which adjusts the distance between the substrate and the plasma generator on the basis of a bias potential applied from the biasing power source to the holder.

The conveyor may be a unit which adjusts the distance between the substrate and the plasma generator by moving the holder.

In adjusting the distance, the distance between the substrate and the plasma generator may be adjusted so that the sheath surface of a sheath generated on the surface of the holder holding the substrate is located at a position where the density distribution of the plasma becomes uniform.

In adjusting the distance, the distance between the substrate and the plasma generator may be adjusted on the basis of the bias potential applied to the holder.

In adjusting the distance, the distance between the substrate and the plasma generator may be adjusted by moving the holder.

The plasma processing apparatus according to the embodiments of the invention includes a conveyor that adjusts the distance between the substrate and the plasma generator.

For this reason, it is possible to move the substrate to the position where the density distribution of the plasma becomes uniform without changing the characteristics of the plasma itself.

According to the embodiments of the invention, it is possible to provide a plasma processing apparatus capable of making the distribution of the plasma on the substrate uniform without changing the characteristics of the plasma itself.

Hereinafter, the preferred embodiment of the invention will be described in detail with reference to the accompanying drawings.

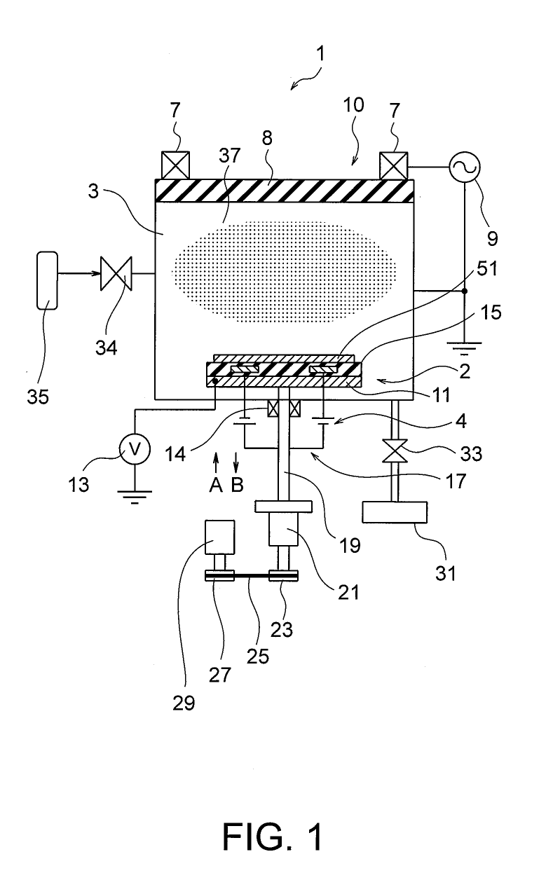

First, a schematic configuration of a plasma processing apparatus 1 according to the embodiment will be described with reference to FIG. 1.

Here, a processing apparatus used in plasma processing of semiconductors is exemplified as the plasma processing apparatus 1.

As shown in FIG. 1, the plasma processing apparatus 1 includes a vacuum container 3 as a chamber.

A dielectric body 8 is provided on the upper surface of the vacuum container 3, and a plasma generating coil 7 is provided on the dielectric body 8 so as to generate plasma 37.

A plasma generating power source 9 is connected to the plasma generating coil 7.

The plasma generating coil 7, the dielectric body 8, and the plasma generating power source 9 constitute a plasma generator (plasma generating device) 10.

On the other hand, a substrate holder 11 is provided inside the vacuum container 3.

An electrostatic chuck 15 is provided in the substrate holder 11 so as to hold the substrate 51 through the use of an electrostatic suction force.

An electrostatic chuck power source 17 is connected to the electrostatic chuck 15 so as to operate the electrostatic chuck 15.

In addition, the electrostatic chuck 15 holds a substrate 51 to be subjected to plasma processing.

Further, the substrate holder 11 is provided with a bias power source 13 as an AC power source or a pulse power source for applying a bias potential to the electrostatic chuck 15 (the dielectric body).

The substrate holder 11, the electrostatic chuck 15, the electrostatic chuck power source 17, and the bias power source 13 constitute a holder (holding unit) 2.

In addition, a support post 19 is connected to the bottom surface of the substrate holder 11.

The support post 19 and the vacuum container 3 are sealed by a vacuum seal 14.

One end of the support post 19 is formed in a screw shape (not shown), and is connected to an elevation mechanism 21 which is a ball screw for moving the support post 19.

A pulley 23 is connected to the elevation mechanism 21.

A pulley 27 is connected to the pulley 23 via a timing belt 25, and an elevation motor 29 is connected to the pulley 27.

Then, the support post 19, the elevation mechanism 21, the pulley 23, the timing belt 25, the pulley 27, and the elevation motor 29 constitute a conveyor (adjustment unit) 4.

When the elevation motor 29 is rotated, the elevation mechanism 21 is driven via the pulley 27, the timing belt 25, and the pulley 23, and the support post 19 is moved in the direction A or B in FIG. 1.

When the support post 19 is moved in the direction A or B in FIG. 1, the substrate holder 11 and the electrostatic chuck 15 are moved in the direction A or B in FIG. 1 along with the support post 19, and the substrate 51 on the electrostatic chuck 15 is also moved in the direction A or B in FIG. 1.

That is, when the elevation motor 29 is rotated, the distance between the substrate 51 and the plasma generator 10 (the dielectric body 8) may be adjusted.

In addition, since the elevation motor 29 is used to adjust the distance between the substrate 51 and the plasma generator 10 (the dielectric body 8), the elevation motor 29 may be configured as a servo motor capable of performing position adjustment.

On the other hand, the vacuum container 3 is provided with a vacuum pump 31 in order to evacuate the vacuum container 3. A vacuum valve 33 is provided between the vacuum pump 31 and the vacuum container 3.

The vacuum container 3 is further provided with a carrier gas source 35 that stores gas to be plasma, and a gas valve 34 is provided between the carrier gas source 35 and the vacuum container 3.

Next, the sequence of the plasma process will be described with reference to FIGS. 1 to 6.

First, the vacuum pump 31 is operated, and then the vacuum valve 33 is opened to evacuate the vacuum container 3.

Subsequently, the gas valve 34 is opened, the carrier gas inside the carrier gas source 35 is introduced into the vacuum container 3, and the pressure inside the vacuum container 3 is constantly maintained by the vacuum valve 33 and the gas valve 34 which can be opened or closed.

Then, the plasma generating coil 7 is operated by using the plasma generating power source 9, and the carrier gas turned to plasma using an induced current.

Further, a bias potential is applied to the electrostatic chuck 15 by using the bias power source 13.

Here, since current most easily flows in an area which is very close to the plasma generating coil 7, plasma 37 is generated in the area which is very close to the coil (refer to FIG. 1).

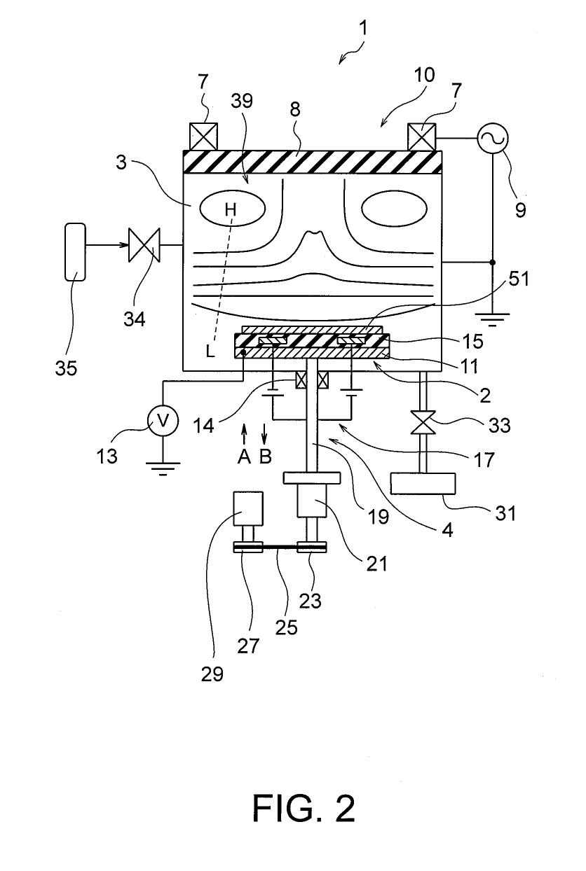

However, since the dielectric body 8 exists between the plasma generating coil 7 and the vacuum container 3, the inside of the vacuum container 3 is a charge-up potential. The density distribution of the generated plasma 37 has a shape shown in the isodensity plasma distribution line 39 in FIG. 2.

Specifically, the highlighted area which is very close to the plasma generating coil 7 corresponds to the area where the density is the highest (refer to the portion marked as “H” in FIG. 2).

Subsequently, as it becomes farther from the plasma generating coil 7, the plasma has a gradually increasing isotropic diffusion shape, and the density of the plasma decreases (refer to the portion marked as “L” in FIG. 2).

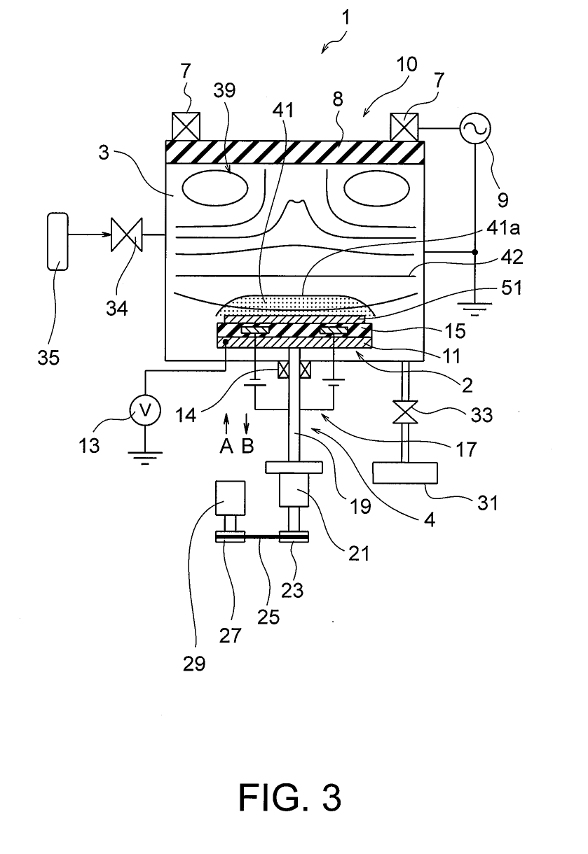

Further, the uniform height 42 shown in FIG. 3 is the position (height) at which the density distribution of the plasma 37 in the height direction becomes uniform.

On the other hand, since the bias potential is applied to the electrostatic chuck 15, the electrostatic chuck 15 inside the plasma serves as an electrode having a bias potential.

Then, as shown in FIG. 3, a sheath 41 is generated on the surface of the electrostatic chuck 15 due to bias potential, plasma density, temperature, and the like.

Since the electric field from the electrode exists inside the sheath 41, the plasma 37 does not exist, and charged particles are simply accelerated in accordance with the electric field.

The thickness d of the sheath 41 is expressed by the following equations (1) and (2) when the electrostatic chuck 15 is a plate electrode.

$$\begin{matrix}0.97 {d}^{2} = {{λ}_{D}^{2} ( \frac{e \cdot {V}_{p}}{k \cdot {T}_{e}} - \frac{1}{2} )}^{\frac{3}{2}} & Equation ( 1 ) \\ {λ}_{D} = {( \frac{{ɛ}_{0} k \cdot {T}_{e}}{{N}_{e} \cdot {e}^{2}} )}^{\frac{1}{2}} & Equation ( 2 )\end{matrix}$$

λ_{D}: Debye length
ε₀: Permittivity of vacuum
k: Boltzmann's constant
Tₑ: Electron temperature
Nₑ: Electron density
e: Electron charge
Vₚ: Applied bias potential

Here, the plasma 37 involved with the plasma process of the substrate 51 is the plasma 37 immediately before the sheath 41 generated by the bias potential applied to the electrostatic chuck 15.

For this reason, when the sheath surface 41 a of the sheath 41 is disposed at the uniform height 42 at which the density distribution of the plasma 37 in the height direction becomes uniform, it is possible to equalize the distribution of the plasma 37 on the substrate 51 and to perform the plasma process uniformly on the surface of the substrate 51.

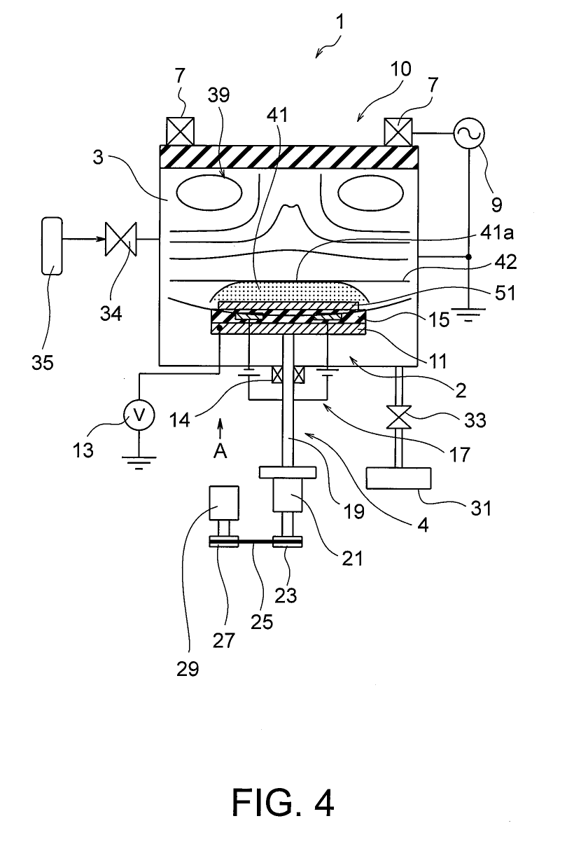

Therefore, as shown in FIG. 4, the position of the holder 2 is adjusted by using the adjustment unit 4 so that the sheath surface 41 a of the sheath 41 is located at the uniform height 42.

Specifically, the sheath thickness d is determined from Equation (1) on the basis of the applied potential (bias potential), and the holder 2 is moved in the direction A or B in FIG. 3 by driving the elevation motor 29 so that the sheath surface 41a is located at the uniform height 42.

For example, since the sheath surface 41 a is located at a position lower than the uniform height 42 in the state of FIG. 3, the holder 2 is moved in the direction A in FIG. 3 so that the sheath surface 41a is located at the uniform height 42 as shown in FIG. 4.

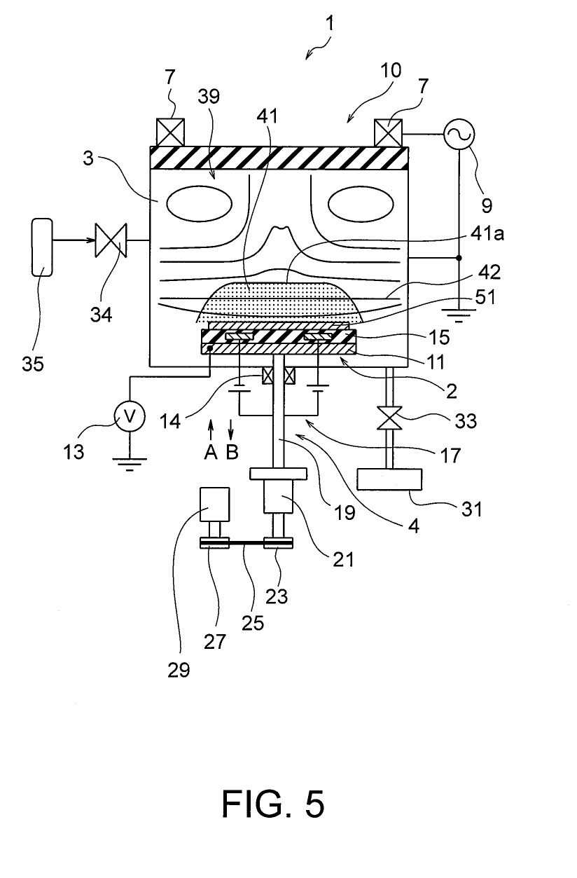

Further, as shown in FIG. 5, when the applied potential (bias potential) is higher than that of the state of FIG. 3, the position of the sheath surface 41a may be higher than the uniform height 42.

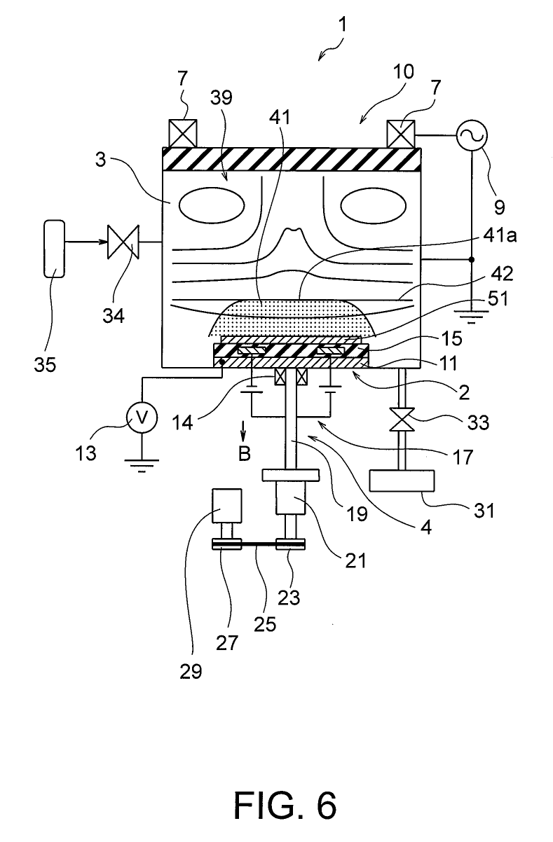

In this case, the holder 2 is moved in the direction of B in FIG. 5 so that the sheath surface 41a is located at the uniform height 42 as shown in FIG. 6.

Then, when the plasma process is performed in the states of FIGS. 4 and 6, it is possible to perform the plasma process uniformly on the surface of the substrate 51.

Here, in any case, since the plasma 37 is not adjusted by the gas pressure, output of the plasma power source, the flow rate, and the like, the characteristics of the plasma 37 are not changed, and the isodensity plasma distribution line 39 is constant.

That is, the plasma processing apparatus 1 is capable of performing the plasma process uniformly on the surface of the substrate 51 just by adjusting the distance between the substrate 51 and the plasma generator 10 without changing the condition of the plasma 37.

Likewise, according to the embodiment, the plasma processing apparatus 1 includes the plasma generator 10, the holder 2, and the adjustment unit 4, and the adjustment unit 4 adjusts the position of the holder 2 so that the sheath surface 41a of the sheath 41 is located at the uniform height 42.

Accordingly, it is possible to perform the plasma process uniformly on the surface of the substrate 51 without changing the characteristics of the plasma 37.

Further, according to the embodiment, the plasma processing apparatus 1 adjusts the position of the holder 2 on the basis of the bias potential applied to the electrostatic chuck 15 from the bias power source 13.

For this reason, even when the bias potential is changed, it is possible to perform the plasma process uniformly on the surface of the substrate 51 without changing the characteristics of the plasma.

### EXAMPLE

Next, the invention will be described in more detail on the basis of the detailed example.

The plasma 37 was generated by using the plasma processing apparatus 1 shown in FIG. 1, and the plasma process was performed on the surface of the substrate 51 by changing the distance between the plasma generator 10 and the substrate 51 in three stages. Then, the uniformity of the surface of the substrate was evaluated by measuring the non-uniformity of the in-plane resistance value of the substrate 51.

The output of the bias power source 13 was set as 135 W and 800 W.

In addition, the distance between the plasma generator 10 and the substrate 51 was set to a relative value in which the distance having the highest uniformity at 135 W was set to 0.

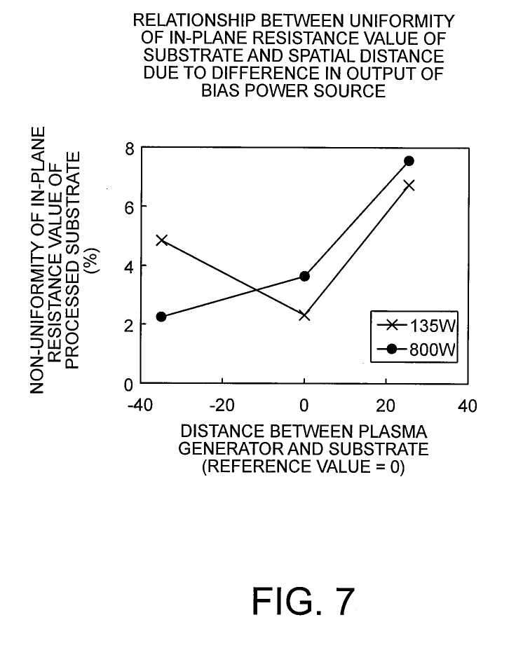

The results are shown in FIG. 7.

As can be understood from FIG. 7, it was found that there is a relationship between the non-uniformity of the in-plane resistance value of the substrate 51 and the distance between the plasma generator 10 and the substrate 51, and the non-uniformity of the in-plane resistance value can be adjusted by adjusting the distance.

It is found that the distance having the smallest non-uniformity (having the highest uniformity) of the in-plane resistance value is seen particularly at 135 W, and the distance between the plasma generator 10 and the substrate 51 is optimized.

That is, it is found that the plasma process can be performed uniformly on the surface of the substrate 51 without changing the characteristics of the plasma even when the bias potential is changed.

In the above-described embodiment, although a case has been described in which the invention is applied to a apparatus used in the semiconductor plasma process, the invention is not, of course, limited thereto, but the invention may be applied to all apparatuses that perform a process on the surface of a specimen by using plasma.

It should be understood that the invention is not limited to the above-described embodiment, but may be modified into various forms on the basis of the concept of the invention. Additionally, the modifications are included in the scope of the invention.

What is claimed is:

1. A plasma processing apparatus comprising:
a plasma generator configured to generate plasma; and
a conveyor configured to adjust a distance between a substrate and the plasma generator.

2. The plasma processing apparatus according to claim 1, further comprising:
a holder configured to hold the substrate; and
a biasing power source configured to apply a bias potential to the holder.

3. The plasma processing apparatus according to claim 2, wherein the conveyor is configured to adjust the distance between the substrate and the plasma generator so that a sheath surface of a sheath generated on the surface of the holder during a plasma process is located at a position where the density distribution of the plasma is uniform.

4. The plasma processing apparatus according to claim 2, wherein the conveyor is configured to adjust the distance between the substrate and the plasma generator based on a bias potential applied from the biasing power source to the holder.

5. The plasma processing apparatus according to claim 2, wherein the conveyor is configured to adjust the distance between the substrate and the plasma generator by moving the holder.

6. A plasma processing method comprising:
generating plasma by a plasma generator to perform a plasma process on a substrate; and
adjusting a distance between the substrate and the plasma generator.

7. The plasma processing method according to claim 6, wherein in adjusting the distance between the substrate and the plasma generator, the distance is adjusted so that a sheath surface of a sheath generated on a surface of a holder holding the substrate is located at a position where the density distribution of the plasma is uniform.

8. The plasma processing method according to claim 6, wherein in adjusting the distance between the substrate and the plasma generator, the distance is adjusted based on a bias potential applied to a holder holding the substrate.

9. The plasma processing method according to claim 6, wherein in adjusting the distance between the substrate and the plasma generator, the distance is adjusted by moving a holder holding the substrate.
